(19) United States
(12) Patent Application Publication
(10) Pub. No.: US 2002/0187639 A1
(43) Pub. Date: Dec. 12, 2002

(54) PROCESS FOR TREATING A POLISHED SEMICONDUCTOR WATER IMMEDIATELY AFTER THE SEMICONDUCTOR WAFER HAS BEEN POLISHED

(76) Inventors: HEINRICH HENNHOFER, ALTOETTING (DE); THOMAS BUSCHHARDT, BURGHAUSEN (DE); FRANZ MANGS, TITTMONING (DE); GERLINDE WENSAUER, ALTOETTING (DE)

Correspondence Address: COLLARD & ROE, 1077 NORTHERN BOULEVARD, ROSLYN, NY, 11576

(21) Appl. No.: 09/032,305

(22) Filed: Feb. 27, 1998

(30) Foreign Application Priority Data
Mar. 6, 1997 (DE) 197 09 217.9

(51) Int. Cl. H01L 21/302; H01L 21/461

(52) U.S. Cl. 438/691

(57) ABSTRACT

A process is provided for treating a polished semiconductor wafer immediately after the semiconductor wafer has been polished. The semiconductor wafer is brought into contact with an aqueous treatment agent solution and its polished surface is oxidized by the action of the aqueous treatment agent solution.

### BACKGROUND OF THE INVENTION

1. Field of the Invention

The present invention relates to a process for treating a polished semiconductor wafer immediately after the semiconductor wafer has been polished.

2. The Prior Art

Polishing the semiconductor wafer represents the final step in the production of the semiconductor wafer and has a decisive influence on the shaping of the semiconductor wafer. The object of the polishing is to create a surface which is as planar, smooth and defect-free as possible on at least one of the two sides of the semiconductor wafer. Such a surface is absolutely imperative if it is to be possible to accommodate functioning electronic structures in high density on the semiconductor wafer. Certain defects on the surface of the semiconductor wafer may later lead to an electronic component failing. These defects can be recognized by a characteristic light scattering behavior and can be indicated in terms of size and number as so-called LPDs (light point defects).

Single side and double side polishing processes are usually employed to polish a semiconductor wafer. In the case of single side polishing (SSP), after the rear side of the semiconductor wafer has been mounted on a suitable support, only the front side is polished. This is done by using a polishing cloth stretched over a polishing plate. On mounting, a form-fitting and force-fitting connection is produced between the rear side and the support. This connection can be, for example by adhesion, adhesive bonding, cementing or the application of a vacuum. Single side polishing processes and devices are usual for single wafer polishing or for polishing batches of wafers. In the case of double side polishing (DSP), the front side and the rear side are polished simultaneously. This is done by guiding a plurality of semiconductor wafers between two, i.e.—upper and lower, polishing plates over which polishing cloths are stretched. In this case, the semiconductor wafers are positioned in thin wafer carriers, which carriers are also used in a similar arrangement when lapping the semiconductor wafers.

The polished surface of a semiconductor wafer has hydrophobic properties. It is very sensitive to uncontrolled chemical attack from an etching agent and it promotes the deposition of particles. Both of these problems can lead to a relatively rapid increase in the number of LPDs. Such an increase in LPD can be avoided by ensuring that the environment is as free of particles as possible. Also the uncontrolled chemical attack from residues of polishing abrasive is suppressed by transferring the semiconductor wafer into a flushing bath or a cleaning bath immediately after the polishing.

On the other hand, it is still possible to observe a rise in the number of LPDs over time even if the semiconductor wafer is stored in deionized water immediately after polishing and is only subsequently subjected to a conventional cleaning procedure. However, in the mass production of semiconductor wafers, waiting times between the polishing and the cleaning of a polished semiconductor wafer are frequently desirable for technical and economic reasons. If every semiconductor wafer had to be cleaned immediately after polishing, single wafer polishing would be necessary. It is very complex technically to achieve this through batch polishing and the process is correspondingly expensive.

### SUMMARY OF THE INVENTION

It is an object of the present invention to provide a process for counteracting the considerable increase in the number of LPDs occurring when a polished semiconductor wafer is not cleaned immediately after the polishing, but rather is stored before it is later cleaned.

The present invention is directed to a process for treating a polished semiconductor wafer comprising polishing a surface of a semiconductor wafer; and immediately after polishing the semiconductor wafer, bringing the semiconductor wafer into contact with an aqueous treatment agent solution for oxidizing the polished surface by action of the aqueous treatment agent solution.

The polished surface of the semiconductor wafer is then coated with a thin film of oxide and has hydrophilic properties. As a result, the semiconductor wafer is less sensitive to residues of polishing abrasive and to particles. After the oxidizing treatment, it can be stored and cleaned in the usual way only at a later time without the risk of having the number of LPDs increase considerably during the storage time.

The treatment agent utilized is an aqueous, oxidizing and alkaline solution. The action of such a solution results in a thin, passivating oxide film present on the polished surface of the semiconductor wafer. It is preferred for the aqueous treatment agent solution to contain hydrogen peroxide (H₂O) as the oxidizing agent along with an alkaline component. This alkaline component is preferably selected from a group of compounds comprising tetramethylammonium hydroxide, ammonium hydroxide, potassium hydroxide, sodium hydroxide, potassium carbonate and mixtures of these compounds.

It is particularly desirable to use an aqueous treatment agent solution which contains the oxidizing agent in a concentration of from 0.02% to 3.0% by volume, preferably from 0.5% to 2.5% by volume, and most preferably from 1% to 2% by volume, based on the total solution volume and the alkaline component in a concentration of from 0.01% to 2.0% by weight, preferably from 0.5% to 1.7% by weight, and most preferably from 0.75% to 1.5% by weight, based upon the total solution weight. The aqueous treatment agent is used at a temperature ranging from 18° C to 650° C. The balance up to 100% by volume, or up to 100% by weight, is water and is based upon the respective total solution volume, or upon the total solution weight.

Furthermore, it has been found that a certain degree of passivation of the polished surface of the semiconductor wafer also occurs if the semiconductor wafer is treated with a surfactant-containing cleaning agent or solution.

The semiconductor wafer can be brought into contact with the treatment agent in various ways. This contact can take place while the semiconductor wafer is still lying on the polishing plate. On the other hand, the semiconductor wafer may also first be removed from the polishing plate and then transferred to a different substrate or into a holder. Accordingly, the oxidizing treatment preferably takes place in the polishing machine or in an unloading station which is connected thereto. The oxidizing treatment can be performed by bringing the polished surface of the semiconductor wafer into contact with a cloth which has been moistened with the aqueous treatment agent or by spraying the polished surface with the treatment agent solution. The semiconductor wafer can also be dipped into a bath of the treatment agent. Treatment using a moistened cloth is preferably carried out in the same way as a polishing operation. Here, the cloth which has been moistened with the aqueous treatment agent solution takes the place of the polishing cloth, and a polishing abrasive is dispensed with.

It is desirable to flush the treatment agent off the semiconductor wafer after the oxidizing treatment is completed, preferably using deionized water. Therefore, the semiconductor wafer is sufficiently protected against undesired attack by a polishing abrasive. The wafer can be stored until it is cleaned in the usual manner, preferably also by using deionized water. The storage time is preferably 15 to 180 minutes, particularly preferably 15 to 30 minutes. The semiconductor wafer is then cleaned. It is preferred to begin cleaning by treating the semiconductor wafer with dilute hydrofluoric acid, which removes the oxide film. The further cleaning of the semiconductor wafer may then comprise, for example, the known RCA cleaning process or a variant of this process.

### DETAILED DESCRIPTION OF PREFERRED EMBODIMENTS

The process of the invention was tested on silicon wafers. To do so, test wafers were treated according to the invention immediately after a standard polishing operation and were then stored in deionized water. The wafers were subsequently subjected to final cleaning, were dried and were examined for LPDs using a commercially available analysis apparatus. Further silicon wafers, as comparative wafers, were polished in the same way, stored in deionized water and cleaned. These comparative wafers were not treated according to the process of the invention immediately after polishing.

The aqueous treatment agent solution utilized according to the invention was an aqueous solution containing 1.5% by volume of hydrogen peroxide and 1.0% by weight of sodium hydroxide, with the balance up to 100% being water. The temperature was 25° C.

The following Table lists the results of the LPD determination. The number given represents the total LPDs>0.12 μm found. The reference parameter is the number of LPDs found on the comparative wafers of type I, normalized to 100%.

TABLE

| Type of wafer | Length of storage | LPDs [%] |
|---|---|---|
| Test wafers I | no storage | 136 |
| Comparative wafers I | no storage | 100 |
| Test wafers II | 3 hours | 96 |
| Comparative wafers II | 3 hours | 400 |
| Test wafers III | 5 hours | 727 |
| Comparative wafers III | 5 hours | 1,878 |

While several embodiments of the present invention have been shown and described, it is to be understood that many changes and modifications may be made thereunto without departing from the spirit and scope of the invention as defined in the appended claims.

What is claimed is:

1. Process for treating a polished semiconductor wafer comprising
polishing a surface of a semiconductor wafer; and
immediately after polishing the semiconductor wafer, bringing the semiconductor wafer into contact with an aqueous treatment agent solution for oxidizing the polished surface by action of the aqueous treatment agent solution.

2. Process according to claim 1, comprising
bringing the semiconductor wafer into contact with the aqueous treatment agent solution containing an oxidizing agent and an alkaline component.

3. Process according to claim 1, comprising
bringing the aqueous treatment agent solution into contact with the semiconductor wafer by spraying the semiconductor wafer with the aqueous treatment agent solution.

4. Process according to claim 1, comprising
bringing the aqueous treatment agent solution into contact with the semiconductor wafer by dipping the semiconductor wafer into the aqueous treatment agent solution.

5. Process according to claim 1, comprising
bringing the aqueous treatment agent solution into contact with the semiconductor wafer by and applying the aqueous treatment agent solution to the polished surface of the semiconductor wafer by means of a cloth which has been moistened with the aqueous treatment agent solution.

6. Process according to claim 1, comprising
bringing the semiconductor wafer into contact with the aqueous treatment agent solution in a polishing machine.

7. Process according to claim 1, comprising
bringing the semiconductor wafer into contact with the aqueous treatment agent solution in an unloading station of a polishing machine.

8. The process as claimed in claim 1, comprising
storing the semiconductor wafer in deionized water after contact with the aqueous treatment agent solution.

9. The process as claimed in claim 1,
wherein the aqueous treatment agent solution comprises an aqueous solution of
(1) from 0.02% to 3.0% by volume, based upon the total solution volume, of an oxidizing agent;
(2) from 0.01% to 2.0% by weight, based upon the total solution weight, of an alkaline component; and
(3) the balance up to 100% by volume being water based upon the total solution volume, and the balance up to 100% by weight being water, which is based upon the total solution weight.

10. The process as claimed in claim 1,
wherein the aqueous treatment agent is at a temperature range of from 18° C. to 65° C.

11. The process as claimed in claim 2,
wherein the oxidizing agent is hydrogen peroxide and the alkaline component is selected from the group consisting of tetramethylammonium hydroxide, ammonium hydroxide, potassium hydroxide, sodium hydroxide, potassium carbonate and the mixtures thereof.

12. The process as claimed in claim 9,
wherein the oxidizing agent is hydrogen peroxide and the alkaline component is selected from the group consisting of tetramethylammonium hydroxide, ammonium hydroxide, potassium hydroxide, sodium hydroxide, potassium carbonate and the mixtures thereof.
